(19) United States
(12) Patent Application Publication
(10) Pub. No.: US 2020/0176278 A1
(43) Pub. Date: Jun. 4, 2020

(54) WAFER DRYING EQUIPMENT AND METHOD THEREOF

(71) Applicant: NANYA TECHNOLOGY CORPORATION, New Taipei City (TW)

(72) Inventors: Shyue-Ru DOONG, Taipei City (TW); Feng-Ju TSAI, Hsinchu County (TW)

(21) Appl. No.: 16/232,040

(22) Filed: Dec. 25, 2018

Related U.S. Application Data
(60) Provisional application No. 62/775,366, filed on Dec. 4, 2018.

(51) Int. Cl. H01L 21/67; F26B 5/00

(52) U.S. Cl. CPC H01L 21/67034; F26B 5/00

(57) ABSTRACT

A wafer drying equipment includes a base, a casing and an electrostatic generator. The base is configured to support a wafer. The casing has an inner wall. The inner wall defines a chamber. The chamber is configured to accommodate the wafer. The electrostatic generator is electrically connected to the casing and is configured to generate an electrostatic charge to the inner wall.

### CROSS-REFERENCE TO RELATED APPLICATION

This application claims priority to U.S. Provisional Application Ser. No. 62/775,366, filed Dec. 4, 2018, the disclosures of which are incorporated herein by reference in their entireties.

### BACKGROUND

### Technical Field

The present disclosure relates to wafer drying equipment.

### Description of Related Art

In the semiconductor industry, a wide variety of manufacturing and testing processes are involved. In some processes, chemical treatment is involved in which chemical solution contacts and reacts with the wafers.

After the chemical treatment to the wafers, the wafers should be made dry first to avoid damage of the wafers and to maintain the performing accuracy in the subsequent processes.

### SUMMARY

A technical aspect of the present disclosure is to provide a wafer drying equipment, which can dry a wafer in an effective manner.

According to an embodiment of the present disclosure, a wafer drying equipment includes a base, a casing and an electrostatic generator. The base is configured to support a wafer. The casing has an inner wall. The inner wall defines a chamber. The chamber is configured to accommodate the wafer. The electrostatic generator is electrically connected to the casing and is configured to generate an electrostatic charge to the inner wall.

In one or more embodiments of the present disclosure, the wafer drying equipment further includes a rotator. The rotator is connected with the base and is configured to rotate the base.

In one or more embodiments of the present disclosure, a rotating speed of the base is ranging from about 300 rpm to about 500 rpm.

In one or more embodiments of the present disclosure, the wafer drying equipment further includes a deionized liquid supplier. The deionized liquid supplier is configured to supply a deionized liquid to the inner wall.

In one or more embodiments of the present disclosure, the deionized liquid is deionized water.

In one or more embodiments of the present disclosure, the base is spaced apart from the inner wall.

In one or more embodiments of the present disclosure, the casing is made of Teflon.

According to another embodiment of the present disclosure, a method for drying a wafer is provided. The method includes rotating the wafer in a chamber; and generating an electrostatic charge to an inner wall defining the chamber.

In one or more embodiments of the present disclosure, the method further includes stopping rotating the base; stopping generating the electrostatic charge to the inner wall; removing the wafer from the chamber; and supplying a deionized liquid to the inner wall.

In one or more embodiments of the present disclosure, the supplying of the deionized liquid includes flowing the deionized liquid along the inner wall.

In one or more embodiments of the present disclosure, the deionized liquid is deionized water.

When compared with the prior art, the above-mentioned embodiments of the present disclosure have at least the following advantages:

(1) Since the rotation of the wafer generates a flowing field above the wafer, such that the water particles and chemical residues are lifted up and moved away from the wafer, the wafer is made dry in an effective manner.

(2) Since the electrostatically charged water particles and chemical residues are attracted by the electrostatically charged inner wall of the casing and are consequently adhered on the electrostatically charged inner wall of the casing, the electrostatically charged water particles and chemical residues do not fall back on the surface of the wafer.

### BRIEF DESCRIPTION OF THE DRAWINGS

The disclosure can be more fully understood by reading the following detailed description of the embodiments, with reference made to the accompanying drawings as follows:

FIG. 1 is a sectional view of a wafer drying equipment according to an embodiment of the present disclosure; and

FIG. 2 is a sectional view of the wafer drying equipment, in which the inner wall of the casing is being cleaned.

### DETAILED DESCRIPTION

Drawings will be used below to disclose embodiments of the present disclosure. For the sake of clear illustration, many practical details will be explained together in the description below. However, it is appreciated that the practical details should not be used to limit the claimed scope. In other words, in some embodiments of the present disclosure, the practical details are not essential. Moreover, for the sake of drawing simplification, some customary structures and elements in the drawings will be schematically shown in a simplified way. Wherever possible, the same reference numbers are used in the drawings and the description to refer to the same or like parts.

Unless otherwise defined, all terms (including technical and scientific terms) used herein have the same meanings as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

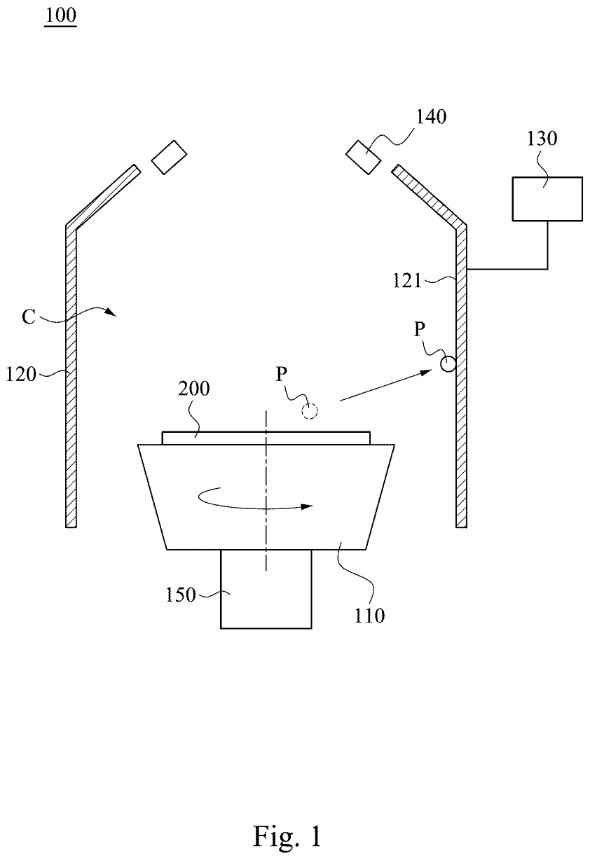

Reference is made to FIG. 1. FIG. 1 is a sectional view of a wafer drying equipment 100 according to an embodiment of the present disclosure. In this embodiment, as shown in FIG. 1, a wafer drying equipment 100 includes a base 110, a casing 120 and an electrostatic generator 130. The base 110 is configured to support a wafer 200. The casing 120 has an inner wall 121. The inner wall 121 defines a chamber C. The chamber C is configured to accommodate the wafer 200. In practical applications, the casing 120 is made of Teflon. The electrostatic generator 130 is electrically connected to the casing 120. Moreover, the electrostatic generator 130 is configured to generate an electrostatic charge to the inner wall 121 of the casing 120.

Furthermore, in this embodiment, the wafer drying equipment 100 further includes a rotator 150. The rotator 150 is connected with the base 110. Moreover, the rotator 150 is configured to rotate the base 110.

During the operation of the drying process to the wafer 200 by the wafer drying equipment 100, the wafer 200 is first supported by the base 110. In other words, the wafer 200 is accommodated in the chamber C defined by the inner wall 121 of the casing 120. Moreover, the base 110 is rotated by the rotator 150. In practice, for instance, the rotating speed of the base 110 is ranging from about 300 rpm to about 500 rpm. This means, the wafer 200 is also rotated at a speed of about 300 rpm to about 500 rpm.

During the rotation of the wafer 200 as mentioned above, the water particles and chemical residues P remained on the surface of the wafer 200 from previous manufacturing process become separated from the wafer 200. To be specific, the rotation of the wafer 200 generates a flowing field above the wafer 200, such that the water particles and chemical residues P are lifted up and moved away from the wafer 200. In this way, the wafer 200 is made dry in an effective manner.

At the same period of time, the electrostatic generator 130 is turned on such that the electrostatic generator 130 generates an electrostatic charge to the inner wall 121 of the casing 120. The electrostatic charge of the inner wall 121 of the casing 120 then induces an electrostatic charge on each of the water particles and chemical residues P lifted up above the wafer 200. In this way, the electrostatically charged water particles and chemical residues P are attracted by the electrostatically charged inner wall 121 of the casing 120 and are consequently adhered on the electrostatically charged inner wall 121 of the casing 120. Therefore, the electrostatically charged water particles and chemical residues P do not fall back on the surface of the wafer 200.

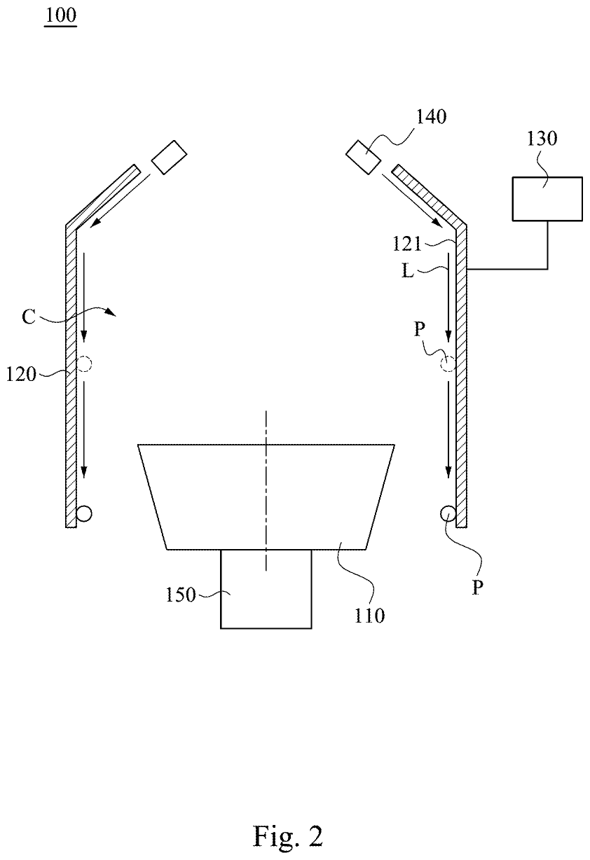

Reference is made to FIG. 2. FIG. 2 is a sectional view of the wafer drying equipment 100, in which the inner wall 121 of the casing 120 is being cleaned. In this embodiment, as shown in FIGS. 1-2, the wafer drying equipment 100 further includes a deionized liquid supplier 140. The deionized liquid supplier 140 is configured to supply a deionized liquid L to the inner wall 121 of the casing 120.

As mentioned above, the electrostatically charged water particles and chemical residues P are attracted and consequently adhered on the electrostatically charged inner wall 121 of the casing 120. After the wafer 200 is made dry, the rotator 150 is turned off and the base 110 and thus the wafer 200 are stopped from rotating. The dry wafer 200 is then removed from the chamber C defined by the inner wall 121 of the casing 120, as shown in FIG. 2. Moreover, the electrostatic generator 130 is turned off such that the electrostatic generator 130 is no longer generating an electrostatic charge to the inner wall 121 of the casing 120.

After the wafer 200 is removed from the chamber C and the electrostatic generator 130 is turned off, the deionized liquid supplier 140 is turned on to supply a deionized liquid L to the inner wall 121 of the casing 120. To be specific, the deionized liquid L is flown along the inner wall 121 of the casing 120. In this way, the water particles and chemical residues P adhered on the inner wall 121 of the casing 120, as mentioned above, are washed away from the inner wall 121. Therefore, the inner wall 121 of the casing 120 is cleaned in an easy and simple manner. In practical applications, the deionized liquid L is deionized water. However, this does not intend to limit the present disclosure.

Structurally speaking, as shown in FIGS. 1-2, the base 110 is spaced apart from the inner wall 121 of the casing 120. Therefore, the water particles and chemical residues P washed away from the inner wall 121 of the casing 120 can flow together with the deionized liquid L through the space between the base 110 and the inner wall 121 of the casing 120. Moreover, during the rotation of the base 110 as mentioned above, the base 110 is not interfered by the casing 120.

In conclusion, when compared with the prior art, the aforementioned embodiments of the present disclosure have at least the following advantages:

(1) Since the rotation of the wafer generates a flowing field above the wafer, such that the water particles and chemical residues are lifted up and moved away from the wafer, the wafer is made dry in an effective manner.

(2) Since the electrostatically charged water particles and chemical residues are attracted by the electrostatically charged inner wall of the casing and are consequently adhered on the electrostatically charged inner wall of the casing, the electrostatically charged water particles and chemical residues do not fall back on the surface of the wafer.

Although the present disclosure has been described in considerable detail with reference to certain embodiments thereof, other embodiments are possible. Therefore, the spirit and scope of the appended claims should not be limited to the description of the embodiments contained herein.

It will be apparent to the person having ordinary skill in the art that various modifications and variations can be made to the structure of the present disclosure without departing from the scope or spirit of the present disclosure. In view of the foregoing, it is intended that the present disclosure cover modifications and variations of the present disclosure provided they fall within the scope of the following claims.

What is claimed is:

1. A wafer drying equipment, comprising:
a base configured to support a wafer;
a casing having an inner wall defining a chamber, the chamber being configured to accommodate the wafer; and
an electrostatic generator electrically connected to the casing and configured to generate an electrostatic charge to the inner wall.

2. The wafer drying equipment of claim 1, further comprising:
a rotator connected with the base and configured to rotate the base.

3. The wafer drying equipment of claim 2, wherein a rotating speed of the base is ranging from about 300 rpm to about 500 rpm.

4. The wafer drying equipment of claim 1, further comprising:
a deionized liquid supplier configured to supply a deionized liquid to the inner wall.

5. The wafer drying equipment of claim 4, wherein the deionized liquid is deionized water.

6. The wafer drying equipment of claim 1, wherein the base is spaced apart from the inner wall.

7. The wafer drying equipment of claim 1, wherein the casing is made of Teflon.

8. A method for drying a wafer, the method comprising:
rotating the wafer in a chamber; and
generating an electrostatic charge to an inner wall defining the chamber.

9. The method of claim 8, further comprising:
stopping rotating the base;
stopping generating the electrostatic charge to the inner wall;
removing the wafer from the chamber; and
supplying a deionized liquid to the inner wall.

10. The method of claim 9, wherein the supplying of the deionized liquid comprises:
flowing the deionized liquid along the inner wall.

11. The method of claim 9, wherein the deionized liquid is deionized water.
